(19) United States
(12) Patent Application Publication
(10) Pub. No.: US 2026/0182144 A1
(43) Pub. Date: Jun. 25, 2026

(54) LIGHT-EMITTING DEVICE

(71) Applicant: Sharp Display Technology Corporation, Kameyama City, Mie (JP)

(72) Inventor: Masanobu MIZUSAKI, Kameyama City, Mie (JP)

(21) Appl. No.: 18/856,931

(22) PCT Filed: Jun. 8, 2022
(86) PCT No.: PCT/JP2022/023053

§ 371 Date: Oct. 15, 2024

(51) Int. Cl. H10K 50/84; H10H 20/855; H10H 20/857

(52) U.S. Cl. CPC H10K 50/846; H10H 20/855; H10H 20/857

(57) ABSTRACT

A light-emitting device includes: a light-emitting element; a first inorganic film covering the light-emitting element; a hydrophobic organic film located outside the first inorganic film; and a hygroscopic film located outside the hydrophobic organic film.

### TECHNICAL FIELD

The disclosure relates to a light-emitting device including a light-emitting element.

### BACKGROUND ART

PTL 1 discloses an organic light-emitting display device including an organic light-emitting element sealed by a thin sealing film containing a hydrophilic polymer film and an inorganic protection film.

### CITATION LIST

### Patent Literature

PTL 1: JP 2011-113967 A

### SUMMARY

### Technical Problem

In the organic light-emitting display device described in PTL 1, foreign matters such as moisture absorbed in the hydrophilic polymer film through a pin hole or the like of the inorganic protection film may be released toward the organic light-emitting element, and thus, the organic light-emitting element may deteriorate.

### Solution to Problem

A light-emitting device according to an embodiment of the disclosure includes a light-emitting element, a first inorganic film covering the light-emitting element, a hydrophobic organic film located outside the first inorganic film, and a hygroscopic film located outside the hydrophobic organic film.

### Advantageous Effects of Disclosure

The release of foreign matters such as moisture absorbed by a hygroscopic film toward a light-emitting element is reduced, so as to decrease the deterioration of the light-emitting element.

### BRIEF DESCRIPTION OF DRAWINGS

FIG. 1 is a schematic cross-sectional view of a light-emitting device according to a first embodiment.

FIG. 2 is an enlarged schematic view of a cross-section of the light-emitting device according to the first embodiment.

FIG. 3 is a schematic cross-sectional view of a light-emitting device according to a second embodiment.

FIG. 4 is a schematic cross-sectional view of a light-emitting device according to a third embodiment.

FIG. 5 is a schematic cross-sectional view of a light-emitting device according to a fourth embodiment.

FIG. 6 is a schematic cross-sectional view of a light-emitting device according to a fifth embodiment.

### DESCRIPTION OF EMBODIMENTS

### First Embodiment

### Light-Emitting Device: Outline

In the present embodiment, description is given using a light-emitting device including a light-emitting element of electrical field injection type as an example.

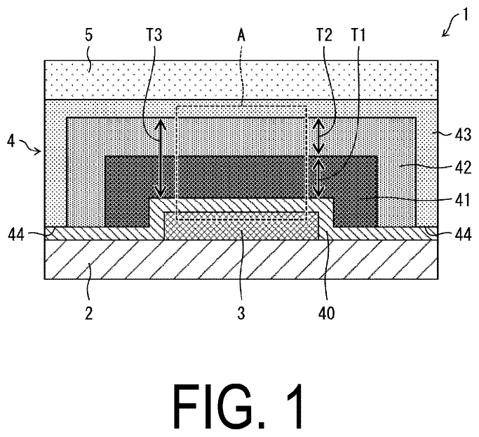

FIG. 1 is a schematic cross-sectional view of a light-emitting device 1 according to the present embodiment. Note that, each of the schematic cross-sectional views of the light-emitting device 1 in the present specification illustrates a cross-section in a direction passing through a light-emitting element described later and substantially parallel to a layering direction of the light-emitting element.

As illustrated in FIG. 1, the light-emitting device 1 includes a substrate 2, a light-emitting element 3, a sealing layer 4, and a cover film 5. In particular, the light-emitting device 1 includes the light-emitting element 3 on the substrate 2, and the sealing layer 4 that covers the light-emitting element 3 and seals the light-emitting element 3 between the substrate 2 and the sealing layer 4. Furthermore, the cover film 5 may be bonded to the sealing layer 4 on a side opposite to the substrate 2.

Each component of the light-emitting device 1 may be a flexible member that can be bent, or may have a film thickness at which the component can be bent. In this case, the light-emitting device 1 may be configured as a flexible device.

### Light-Emitting Device: Substrate

The substrate 2 may be, for example, a glass substrate or a resin film substrate including a drive circuit capable of individually driving any one of the electrodes of the light-emitting element 3 described later. For example, the substrate 2 may include a drive circuit including a metal material or a transparent material having electrical conductivity.

### Light-Emitting Device: Light-Emitting Element

The light-emitting element 3 is an element that is driven by the above-described drive circuit of the substrate 2 to emit light, and is, for example, a layered electric field injection type light-emitting element having a light-emitting layer containing a light-emitting material between electrodes. For example, the light-emitting element 3 may be a quantum dot light-emitting element containing semiconductor nanoparticles (quantum dots) as a light-emitting material in the light-emitting layer, or an organic light-emitting element (for example, an OLED element) containing an organic fluorescent material or an organic phosphorescent material in the light-emitting layer. The light-emitting element 3 may contain a mixture of a host material and a dopant material in the light-emitting layer.

The light-emitting material contained in the light-emitting element 3 may include a light-emitting material that emits light of any color including red, green, and blue, or may include at least two or more types of these light-emitting materials. Note that, in the present specification, “red light” refers to, for example, light having a light-emitting central wavelength in a wavelength band of greater than 600 nm and 780 nm or less. Furthermore, “green light” refers to, for example, light having a light-emitting central wavelength in a wavelength band of greater than 500 nm and 600 nm or less. Moreover, “blue light” refers to, for example, light having a light-emitting central wavelength in a wavelength band 400 nm or greater and 500 nm or less.

More specifically, the light-emitting element 3 may include, for example, an anode, a hole injection layer, a hole transport layer, an electron blocking layer, a light-emitting layer, a hole blocking layer, an electron transport layer, an electron injection layer, and a cathode, in this order from the side of the substrate 2. However, the layering order of the layers of the light-emitting element 3 may be a reverse order to the order described above.

When the light-emitting element 3 is driven by the drive circuit of the substrate 2, holes and electrons may be respectively injected from the anode and the cathode of the light-emitting element 3 toward the light-emitting layer. The hole injection layer, the hole transport layer, and the electron blocking layer may have a function of transporting holes from the anode to the light-emitting layer. The electron injection layer, the electron transport layer, and the hole blocking layer may have a function of transporting electrons from the cathode to the light-emitting layer. The electron blocking layer may have a function of preventing electrons from being transported from the light-emitting layer toward the anode, and the hole blocking layer may have a function of preventing holes from being transported from the light-emitting layer toward the cathode.

The light-emitting material contained in the light-emitting layer of the light-emitting element 3 may be a material that emits light by excitons generated by recombination of holes from the anode and electrons from the cathode. Thus, when the drive circuit of the substrate 2 drives the light-emitting element 3, the light-emitting device 1 may obtain light emitted from the light-emitting layer of the light-emitting element 3. The light emitted from the light-emitting layer of the light-emitting element 3 may be extracted from the light-emitting element 3 toward the cover film 5. In this case, the light-emitting device 1 may include a capping layer between the light-emitting element 3 and the sealing layer 4, in order to control light reflection between the light-emitting element 3 and the sealing layer 4 described later and to increase the extraction efficiency of the light emitted from the light-emitting element 3. Alternatively, when the substrate 2 is a transparent substrate, the light emitted from the light-emitting layer of the light-emitting element 3 may be extracted from the light-emitting element 3 toward the substrate 2.

### Light-Emitting Device: Sealing Layer: Outline

The sealing layer 4 seals the light-emitting element 3 between the sealing layer 4 and the substrate 2, and thus, the sealing layer 4 reduces permeation of foreign matters such as moisture from the outside into the light-emitting element 3 on the side of the sealing layer 4 of the light-emitting device 1. As illustrated in FIG. 1, the sealing layer 4 includes a first inorganic film 40 covering at least the light-emitting element 3, a hydrophobic organic film 41 located outside the first inorganic film 40, and a hygroscopic film 42 located outside the hydrophobic organic film 41, in this order from the side of the substrate 2 and the light-emitting element 3. In the present embodiment, the sealing layer 4 further includes a second inorganic film 43 that is located further to the outside from the hygroscopic film 42 and covers the hygroscopic film 42.

### Light-Emitting Device: Sealing Layer: First Inorganic Film

For example, the first inorganic film 40 may include at least one type selected from the group consisting of silicon oxide, silicon nitride, magnesium oxide, magnesium nitride, aluminum oxide, aluminum nitride, zinc oxide, and zinc nitride. In particular, the first inorganic film 40 may include silicon oxide or silicon nitride.

The film thickness of the first inorganic film 40 may be 100 nm or greater, so that the first inorganic film 40 sufficiently reduces the permeation of foreign matters such as moisture into the light-emitting element 3 or sufficiently reduces the formation of pin holes described below. When the light-emitting device 1 is a flexible device, the film thickness of the first inorganic film 40 may be 2000 nm or less, so that the first inorganic film 40 is sufficiently flexible.

### Light-Emitting Device: Sealing Layer: Hydrophobic Organic Film

The hydrophobic organic film 41 is an organic sealing film containing an organic material having hydrophobicity, and contains, for example, an acrylic resin. For example, the polarity of the organic material included in the hydrophobic organic film 41 may be lower than the polarity of water. Alternatively, a contact angle between the hydrophobic organic film 41 and water may be 25 degrees or greater.

A film thickness T1 of the hydrophobic organic film 41 may be 50 nm or greater, 100 nm or greater, or 200 nm or greater. When the thickness of the hydrophobic organic film 41 is greater, it is possible to increase the hygroscopicity of the hydrophobic organic film 41 in the light-emitting device 1, and reduce the permeation of foreign matters such as moisture from the outside of the light-emitting device 1 into the light-emitting element 3.

The moisture permeability of the hydrophobic organic film 41 may be 60 g/(m²·24 h) or greater and 1000 g/(m²·24 h) or less. When the moisture permeability of the hydrophobic organic film 41 is 60 g/(m²·24 h) or greater, it is possible to increase the hygroscopicity of the hydrophobic organic film 41 in the light-emitting device 1, and reduce the permeation of foreign matters such as moisture from the outside of the light-emitting device 1 into the light-emitting element 3. When the moisture permeability of the hydrophobic organic film 41 is 1000 g/(m²·24 h) or less, it is possible to reduce the amount of moisture that is absorbed by the hydrophobic organic film 41, passes through the hydrophobic organic film 41, and reaches the side of the first inorganic film 40 in the light-emitting device 1.

### Light-Emitting Device: Sealing Layer: Hygroscopic Film

The hygroscopic film 42 is an organic sealing film having hygroscopicity, and in particular, has a function of delaying the permeation of foreign matters into the light-emitting element 3 by absorbing foreign matters such as moisture that permeates from the outside of the light-emitting device 1 on the side of the sealing layer 4 into the light-emitting element 3. For example, the hygroscopic film 42 may include an organic polymer having hygroscopicity.

In the present embodiment, the hydrophobic organic film 41 and the hygroscopic film 42 may be adjacent to each other. In this case, the hygroscopic film 42 may include an organic polymer having both hygroscopicity and adhesion to the hydrophobic organic film 41. In other words, the hygroscopic film 42 may include an organic polymer having both hydrophilicity and hydrophobicity. In particular, the hygroscopic film 42 may be formed at a position covering the hydrophobic organic film 41.

### Light-Emitting Device: Sealing Layer: Polymer of Hygroscopic Film

For example, the hygroscopic film 42 may include, as the organic polymer having both hydrophilicity and hydrophobicity, a first organic polymer having a hydrophilic functional group and in which at least a part of a molecular backbone is hydrophobic. In particular, the first organic polymer may not have a hydrophobic functional group.

In the present specification, the hydrophilic functional group may refer to a functional group in which the contact angle between water and the surface of the polymer film having the hydrophilic functional group is less than 25 degrees. Alternatively, the hydrophilic functional group may refer to a functional group having a polarity equal to or higher than the polarity of a water molecule. On the other hand, in the present specification, the hydrophobic functional group may refer to a functional group in which the contact angle between water and the surface of the polymer film having the hydrophobic functional group is 25 degrees or greater. Alternatively, a hydrophilic functional group may refer to a functional group having a polarity lower than the polarity of a water molecule.

The hydrophilic functional group of the first organic polymer may include at least one type selected from the group consisting of an amide group and a carboxylic acid group. In particular, the first organic polymer may include at least one type selected from the group consisting of polyamic acid, polyamidic acid, polyimidic acid, partially imidized polyamic acid, and polyacrylic acid. Specifically, the first organic polymer may include at least one type selected from the group consisting of polymers represented by the following General Formula (1):

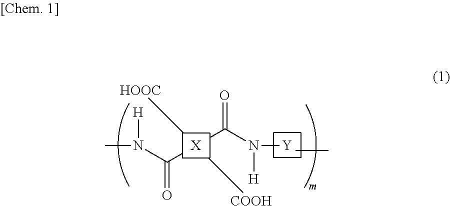

In General Formula (1), X represents any one of the following components:

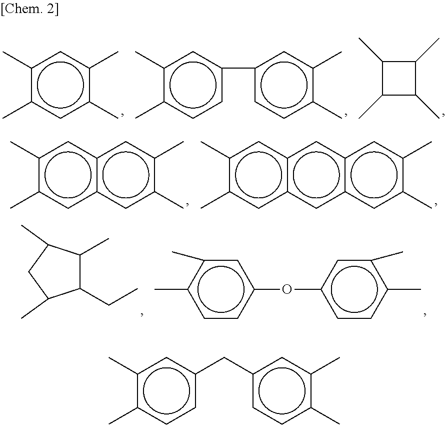

In General Formula (1), Y represents any one of the following components:

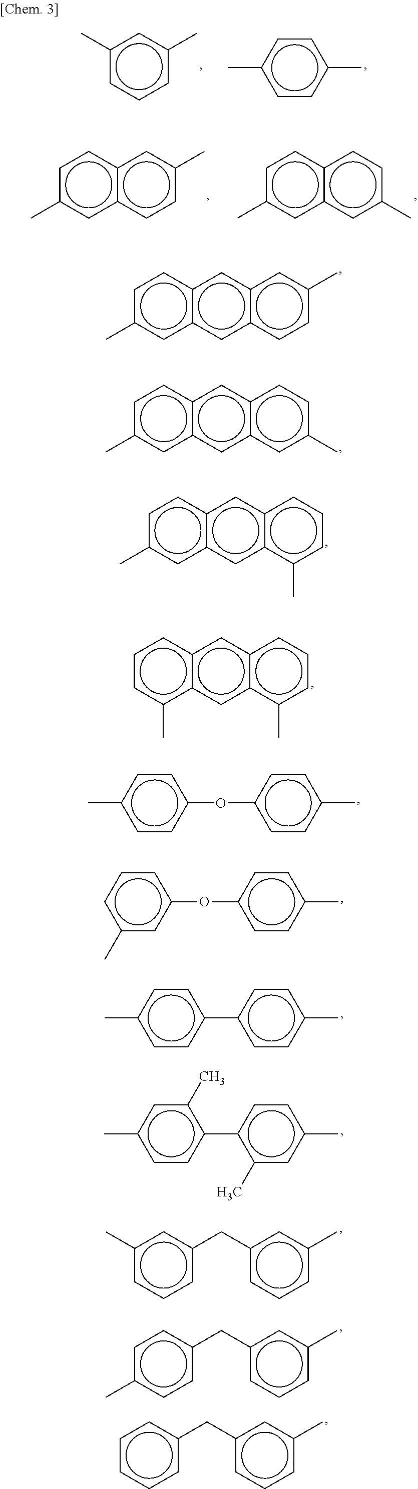

In other words, the polymer represented by General Formula (1) contains a polyamic acid including an amide group and a carboxylic acid group as hydrophilic functional groups. Furthermore, X and Y of the polymer represented by General Formula (1) are parts of a molecular backbone having hydrophobicity.

The first organic polymer may be a polymer obtained by polymerizing a monomer having a hydrophilic functional group. In particular, the first organic polymer may include at least one type selected from the group consisting of polymers represented by the following chemical formulae. In other words, the polymers represented by the following chemical formulae may be obtained by polymerizing a monomer containing a hydrophilic functional group and including a molecular backbone having hydrophobicity.

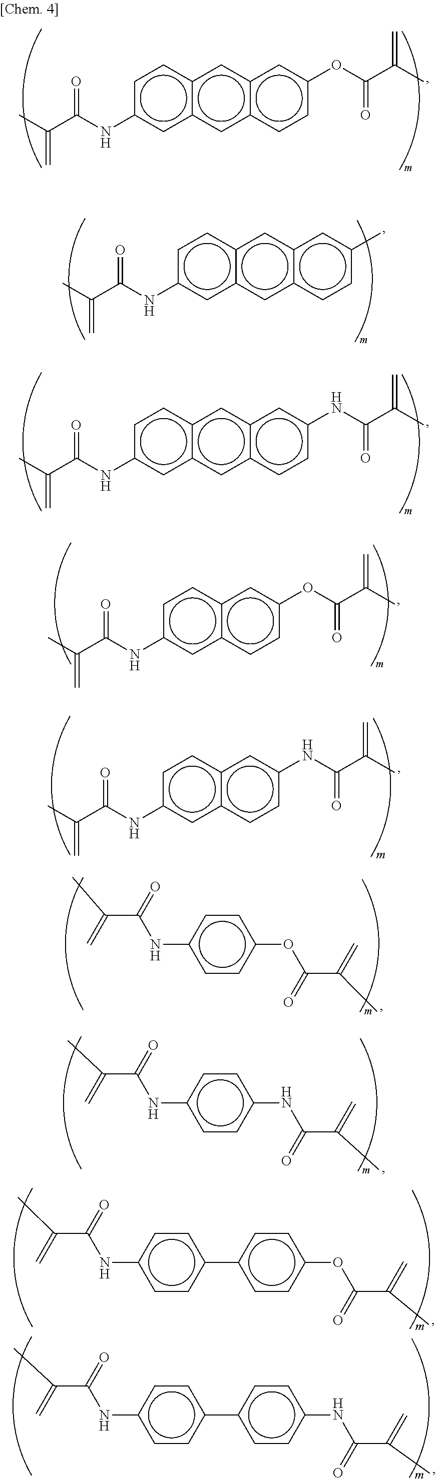

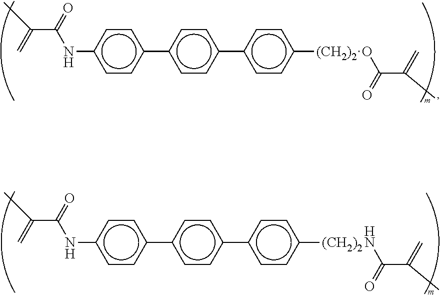

Furthermore, the hygroscopic film 42 may include a second organic polymer having a hydrophilic functional group and a hydrophobic functional group, as the organic polymer having both hydrophilicity and hydrophobicity.

In particular, the hydrophilic functional group of the second organic polymer may include at least one type selected from the group consisting of an amide group and a carboxylic acid group. Furthermore, the hydrophobic functional group of the second organic polymer may include at least one type selected from the group consisting of an alkyl group and a functional group having an aromatic ring. In particular, the second organic polymer may include at least one type selected from the group consisting of polyamic acid, polyamidic acid, polyimidic acid, partially imidized polyamic acid, and polyacrylic acid. Specifically, the second organic polymer may include at least one type selected from the group consisting of polymers represented by the following General Formula (2):

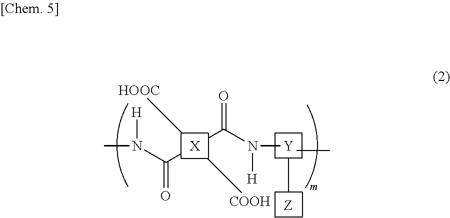

In General Formula (2), X represents any one of the following components:

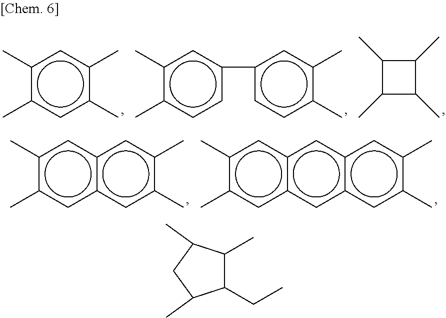

In the General Formula (2), Y represents any one of the following components:

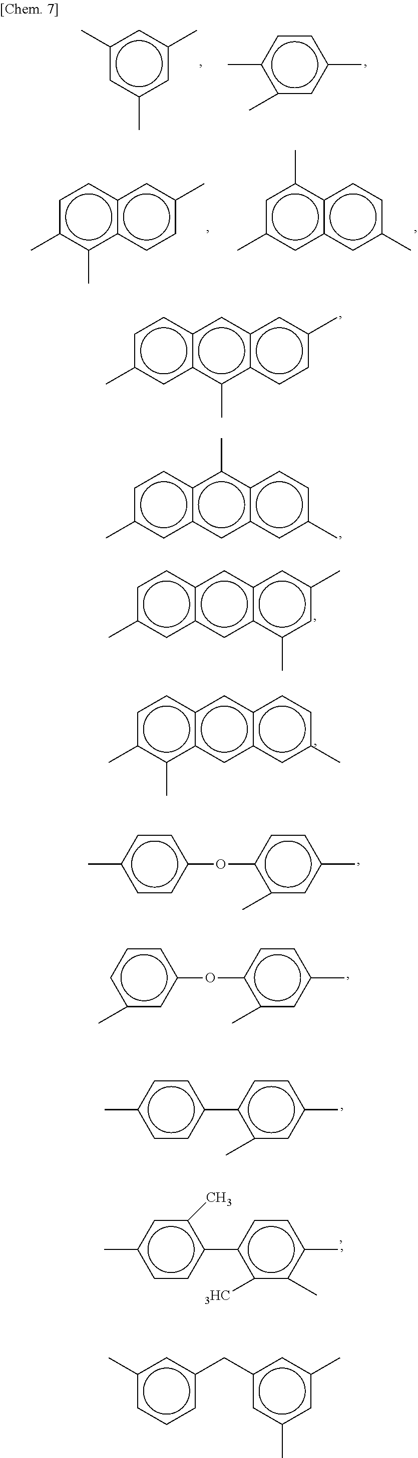

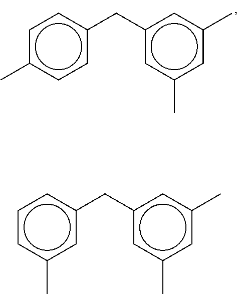

Furthermore, in General Formula (2), Z represents any one of the following components:

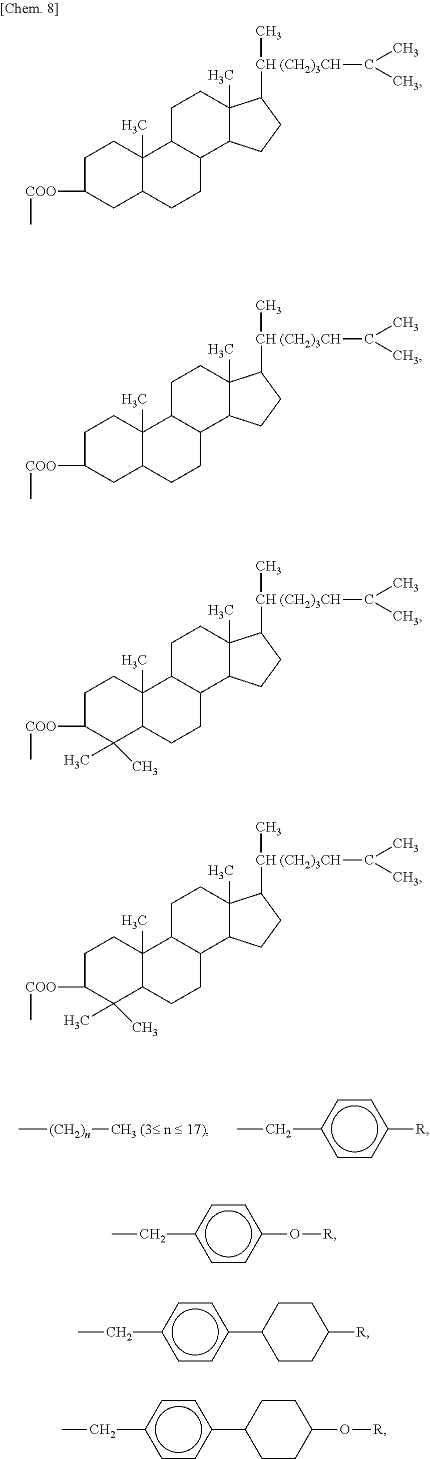

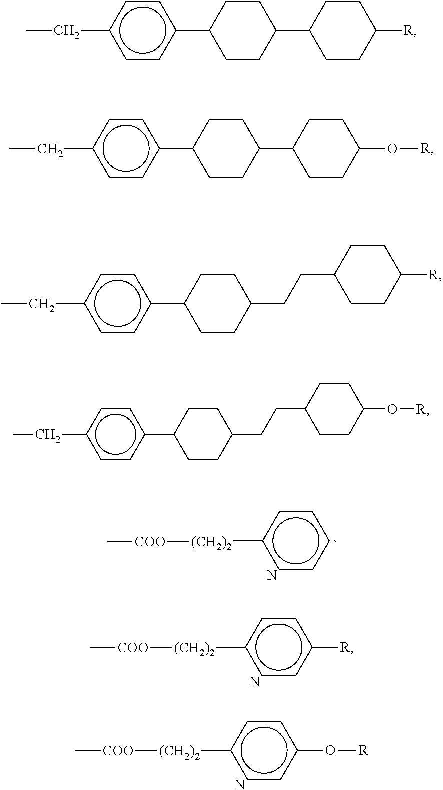

In other words, the polymer represented by General Formula (2) contains a polyamic acid including an amide group and a carboxylic acid group as hydrophilic functional groups. Moreover, X and Y of the polymer represented by General Formula (2) are parts of a molecular backbone having hydrophobicity, and Z is a hydrophobic functional group.

The second organic polymer may be a polymer obtained by polymerizing a monomer having a hydrophilic functional group and a hydrophobic functional group. For example, the second organic polymer may be a polymer obtained by polymerizing a monomer in which a part of a monomer having a hydrophilic functional group is substituted with a hydrophobic functional group. Specifically, the second organic polymer may include at least one type selected from the group consisting of polymers represented by the following chemical formulae in which X represents an alkyl group serving as the hydrophobic functional group.

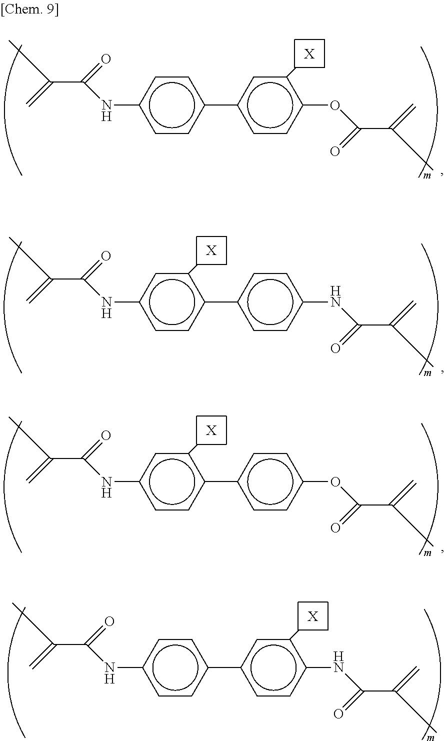

The hygroscopic film 42 may include both the first organic polymer and the second organic polymer described above. In this case, the molecular backbone of the first organic polymer may be the same as the molecular backbone of the second organic polymer. In other words, the hygroscopic film 42 may be formed by substituting a part of the terminal ends or the side chains of the first organic polymer with a hydrophobic functional group. The ratio of the amount of substance in the second organic polymer to the amount of substance in the first organic polymer in the hygroscopic film 42 may be 0.05 or greater and 20 or less, so that both the hygroscopic degree in the hygroscopic film 42 and the adhesion of the hygroscopic film 42 to the hydrophobic organic film 41 can be sufficiently ensured.

The concentration of the second organic polymer in a portion of the hygroscopic film 42 on the side of the hydrophobic organic film 41 may be higher than the concentration of the second organic polymer in a portion of the hygroscopic film 42 on the side opposite to the side of the hydrophobic organic film 41. In other words, when the direction from the substrate 2 to the cover film 5 in the light-emitting device 1 is an upward direction, the concentration of the second organic polymer in an upper portion of the hygroscopic film 42 may be higher than the concentration of the second organic polymer in a lower portion of the hygroscopic film 42. In this case, the adhesion between the hydrophobic organic film 41 and the hygroscopic film 42 improves in the hygroscopic film 42 on the side of the hydrophobic organic film 41. Furthermore, the hygroscopicity improves on the side of the hygroscopic film 42 opposite to the side of the hydrophobic organic film 41, in other words, on the outer side of the light-emitting device 1, and it is possible to reduce the permeation of foreign matters such as moisture from the outside of the light-emitting device 1 into the light-emitting element 3.

### Light-Emitting Device: Sealing Layer: Characteristics of Hygroscopic Film

The moisture permeability of the hygroscopic film 42 may be 30 g/(m²·24 h) or less or 20 g/(m²·24 h) or less, in order to reduce the amount of moisture absorbed by the hygroscopic film 42 that passes through the hygroscopic film 42 and reaches the side of the hydrophobic organic film 41 in the hygroscopic film 42. Furthermore, the moisture permeability of the hygroscopic film 42 may be ⅓ or less or ½ or less of the moisture permeability of the hydrophobic organic film 41, in order to sufficiently ensure the hygroscopicity of the hygroscopic film 42 with respect to the hydrophobic organic film 41.

A film thickness T2 of the hygroscopic film 42 may be 50 nm or greater, 100 nm or greater, or 200 nm or greater. When the thickness of the hygroscopic film 42 is greater, it is possible to increase the hygroscopicity of the hygroscopic film 42 in the light-emitting device 1, and reduce the permeation of foreign matters such as moisture from the outside of the light-emitting device 1 into the light-emitting element 3.

In order to increase the hygroscopicity of both the hydrophobic organic film 41 and the hygroscopic film 42, a total film thickness T3 of the hydrophobic organic film 41 and the hygroscopic film 42 may be 500 nm or greater. In order to ensure both the hygroscopicity of the hydrophobic organic film 41 and the hygroscopic film 42 and the adhesion between the hydrophobic organic film 41 and the hygroscopic film 42, the ratio of the film thickness T2 to the film thickness T1 may be 0.05 or greater and 20 or less.

### Light-Emitting Device: Sealing Layer: Second Inorganic Film

The second inorganic film 43 may have the same configuration as the first inorganic film 40, except for a formation position of the second inorganic film 43. In particular, the second inorganic film 43 may be formed at a position covering the hygroscopic film 42. Here, the first inorganic film 40 may be formed on the substrate 2 up to a position further to an outer peripheral side of the light-emitting device 1 than the hydrophobic organic film 41 and the hygroscopic film 42. In this case, the second inorganic film 43 may be in direct contact of a peripheral portion 44 of the first inorganic film 40. Thus, an outer peripheral side of the light-emitting device 1 is covered with the inorganic sealing film of the sealing layer 4. Therefore, according to the above-described configuration, in the light-emitting device 1, by using the sealing layer 4, it is possible to reduce the permeation of foreign matters such as moisture from the lateral periphery of the light-emitting device 1.

### Light-Emitting Device: Cover Film

The cover film 5 bonded to and formed on a side of the sealing layer 4 opposite to the substrate 2. The cover film 5 may include, for example, a resin material that is light-transmitting. The cover film 5 may be formed to protect the light-emitting element 3 and the sealing layer 4 of the light-emitting device 1. The cover film 5 may include a transparent electrode having electrical conductivity such as an electrode of a touch panel.

### Moisture-Proof Mechanism of Light-Emitting Element by Sealing Layer

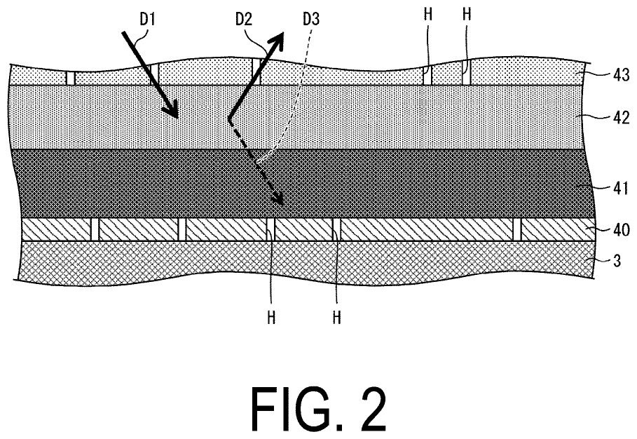

A mechanism for reducing the permeation of foreign matters such as moisture from the outside of the light-emitting device 1 into the light-emitting element 3 by the sealing layer 4 will be described in detail with reference to FIG. 2. FIG. 2 is an enlarged schematic view of a region A of the cross-section of the light-emitting device 1 illustrated in FIG. 1. In other words, FIG. 2 is an enlarged schematic view of a part of the cross-section of the light-emitting device 1 illustrated in FIG. 1 from the vicinity of an end portion of the light-emitting element 3 on the side of the sealing layer 4 to the vicinity of an end portion of the second inorganic film 43 on the side of the hygroscopic film 42.

For example, moisture from the outside of the light-emitting device 1 may pass through the cover film 5 or may pass in-between the cover film 5 and the sealing layer 4, and permeate toward the light-emitting element 3. In the present embodiment, the second inorganic film 43 mainly reduces permeation of moisture into the light-emitting element 3, when moisture permeates the sealing layer 4 from the side of the cover film 5.

Here, as illustrated in FIG. 2, a plurality of fine pin holes H penetrating in a film thickness direction may be formed in the first inorganic film 40 and the second inorganic film 43. For example, the pin holes H may be generated when foreign matters are mixed to the material in a manufacturing process of the first inorganic film 40 and the second inorganic film 43, or when the film thickness of the first inorganic film 40 and the second inorganic film 43 is irregular.

Therefore, as indicated by a permeation direction D1 in FIG. 2, moisture permeating from the side of the cover film 5 of the sealing layer 4 may permeate and reach the hygroscopic film 42 via the pin holes H formed in the second inorganic film 43. Also in this case, the hydrophilic polymer in the hygroscopic film 42 absorbs the moisture, and thus, the sealing layer 4 can delay the penetration of moisture from the outside of the light-emitting device 1 into the light-emitting element 3.

When the hygroscopic film 42 continues to absorb moisture and the hygroscopic film 42 is saturated by the amount of moisture, the moisture may be released from the hygroscopic film 42. Here, the moisture is released from the hygroscopic film 42 toward a release direction D2 or a permeation direction D3 illustrated in FIG. 2. The release direction D2 is a direction in which moisture is released from the hygroscopic film 42 to the outside of the light-emitting device 1 via the pin holes H of the second inorganic film 43. The permeation direction D3 is a direction in which the moisture permeates from the hygroscopic film 42 toward the hydrophobic organic film 41, in other words, toward the light-emitting element 3.

Rather than permeating into the hydrophobic organic film 41 which is hydrophobic and solid, the moisture from the hygroscopic film 42 is more likely to be released to the pin holes H serving as vacancies of the second inorganic film 43. In other words, the moisture from the hygroscopic film 42 is preferentially released toward the release direction D2 rather than the permeation direction D3.

For example, it is assumed that the light-emitting device 1 does not include the second inorganic film 43. In this case, the cover film 5 is attached onto the hygroscopic film 42. However, in this case, a small gap may be formed in a part between the hygroscopic film 42 and the cover film 5. Therefore, also in the above-described case, rather than permeating into the hydrophobic organic film 41 which is hydrophobic and solid, the moisture from the hygroscopic film 42 is preferentially released into the gap between the hygroscopic film 42 and the cover film 5.

Therefore, among the moisture absorbed by the hygroscopic film 42, the amount of moisture released to the outside of the light-emitting device 1 is greater than the amount of moisture permeating into the light-emitting element 3. Thus, the sealing layer 4 efficiently releases the moisture absorbed by the hygroscopic film 42 to the outside of the light-emitting device 1, and reduces the permeation of moisture into the light-emitting element 3.

Furthermore, the hydrophobic organic film 41 also has a certain degree of film thickness and hygroscopicity, so that, even when moisture permeates from the hygroscopic film 42 into the hydrophobic organic film 41, the hydrophobic organic film 41 can delay the permeation of the moisture into the light-emitting element 3. Additionally, the first inorganic film 40 reduces the release of moisture from the hydrophobic organic film 41 to the light-emitting element 3.

As described above, the sealing layer 4 can more effectively reduce the permeation of moisture from the outside of the light-emitting device 1 into the light-emitting element 3. In addition to moisture, the sealing layer 4 can also reduce the permeation of liquid foreign matters from the outside of the light-emitting device 1 into the light-emitting element 3 by a mechanism similar to the one described above.

As described above, the hygroscopic film 42 includes a polymer having a hydrophobic functional group or a polymer including a molecular backbone having hydrophobicity. Therefore, it is possible to increase the adhesion between the hygroscopic film 42 and the hydrophobic organic film 41 having hydrophobicity. When the hydrophobic organic film 41 and the hygroscopic film 42 are in closer contact with each other, the sealing layer 4 can further reduce the permeation of foreign matters such as moisture from in-between the hydrophobic organic film 41 and the hygroscopic film 42.

### Evaluation of Characteristics of Light-Emitting Device: Example 1

A light-emitting device according to an example in which a light-emitting element is sealed with a sealing layer having the same configuration as the sealing layer 4 according to the above-described embodiment was manufactured, and characteristics of the light-emitting device were compared with those of light-emitting devices according to comparative examples. A light-emitting device was manufactured by the procedure described below as a light-emitting device according to Example 1.

First, the substrate 2 was prepared including a drive circuit and Ag and ITO as an anode of the light-emitting element 3. Next, a hole injection layer, a hole transport layer, an electron blocking layer, a light-emitting layer, a hole blocking layer, an electron transport layer, an electron injection layer, and a cathode each having a predetermined film thickness were formed by vapor deposition under predetermined vapor deposition conditions on the anode formed on the substrate 2. Here, an organic fluorescent material emitting blue light was employed as the light-emitting material of the light-emitting layer. The electron injection layer was formed by vapor-depositing LiF, and the cathode was formed by vapor-depositing a metal material containing Mg and Ag. Thus, a blue OLED element of top-emitting type was formed as the light-emitting element 3 on the substrate 2. Note that, in Example 1, a capping layer formed of an organic material was formed on the blue OLED element.

Next, a SiN film having a film thickness of 0.1 μm was film-formed on the substrate 2 and the light-emitting element 3 by a sputtering method, to form the first inorganic film 40. Subsequently, an acrylic resin material having photocurability was film-formed on the first inorganic film 40, and then, the acrylic resin material was irradiated with light to form the hydrophobic organic film 41 having a film thickness of 0.5 μm.

Next, the hygroscopic film 42 was formed by the method described below. First, a polymer material containing a polyamic acid having an alkyl group in a side chain and a polyamic acid not having an alkyl group in a side chain in a weight ratio of 20:80 was synthesized. The polymer material was applied to form a film and the film was heated at 200° C. Thus, the hygroscopic film 42 having a film thickness of 0.5 μm was formed. Furthermore, a SiN film having a film thickness of 0.1 μm was film-formed by a sputtering method to form the second inorganic film 43, and thus, the sealing layer 4 was formed. Accordingly, the light-emitting device according to Example 1 was obtained. Note that, in the light-emitting device according to Example 1, the moisture permeability of the hydrophobic organic film 41 is 60 g/(m²·24 h), and the moisture permeability of the hygroscopic film 42 is 25 g/(m²·24 h).

### Evaluation of Characteristics of Light-Emitting Device: Comparative Examples 1 to 4

In order to evaluate the characteristics of the light-emitting device according to Example 1, light-emitting devices according to Comparative Examples 1 to 4 were also manufactured. The light-emitting device according to each of the comparative examples were manufactured by changing, as described below, the configuration of the sealing layer 4 in the light-emitting device according to Example 1 described above. Note that, in the sealing layer according to each of the comparative examples, the film thickness and the material of the first inorganic film 40 and the second inorganic film 43 are the same as the film thickness and the material of the first inorganic film 40 and the second inorganic film 43 according to Example 1. Furthermore, in the sealing layer according to each of the comparative examples, the materials of the hydrophobic organic film 41 and the hygroscopic film 42 are the same as the materials of the hydrophobic organic film 41 and the hygroscopic film 42 according to Example 1.

The sealing layer of the light-emitting device according to Comparative Example 1 includes the first inorganic film 40, the hydrophobic organic film 41 having a film thickness of 1 μm, and the second inorganic film 43, from the side of the light-emitting element 3. The sealing layer of the light-emitting device according to Comparative Example 2 includes the first inorganic film 40, the hygroscopic film 42 having a film thickness of 20 nm, the hydrophobic organic film 41 having a film thickness of 1 μm, and the second inorganic film 43, from the side of the light-emitting element 3. The sealing layer of the light-emitting device according to Comparative Example 3 includes the first inorganic film 40, the hygroscopic film 42 having a film thickness of 1 μm, and the second inorganic film 43, from the side of the light-emitting element 3. The sealing layer of the light-emitting device according to Comparative Example 4 includes the first inorganic film 40, the hygroscopic film 42 having a film thickness of 0.13 μm, the hydrophobic organic film 41 having a film thickness of 0.2 μm, and the second inorganic film 43, from the side of the light-emitting element 3.

### Evaluation of Characteristics of Light-Emitting Devices: Results of Evaluation

The characteristics of the light-emitting devices according to Example 1 and each of the comparative examples were measured and summarized in the following Table 1.

TABLE 1

| | External quantum | Chromaticity | Lifetime |
|---|---|---|---|
| | efficiency (%) | (x, y) | (h) |
| Example 1 | 13.1 | (0.14, 0.045) | 145 |
| Comparative Example 1 | 13.1 | (0.14, 0.045) | 90 |
| Comparative Example 2 | 12.8 | (0.14, 0.045) | 90 |
| Comparative Example 3 | 13.2 | (0.14, 0.043) | 115 |
| Comparative Example 4 | 13.0 | (0.14, 0.044) | 120 |

Note that, in the tables of the present specification including Table 1, the column labeled with “External quantum efficiency (%)” indicates the external quantum efficiency of the light-emitting element 3 of each light-emitting device. The column labeled with “Chromaticity (x, y)” indicates coordinates on the chromaticity coordinates of light having a central wavelength among the light emission obtained from each light-emitting device. The column labeled with “Lifetime (h)” indicates the time required for the brightness of each light-emitting device to reach 90% of an initial brightness, when the current drive at 50 mA/cm² is tested in an environment including a temperature of 45° C. and 90% RH.

As can be understood from Table 1, the external quantum efficiency of the light-emitting element 3 and the chromaticity of light from the light-emitting element 3 were hardly different between Example 1 and each of the comparative examples. In other words, the above indicates that, in Example 1, the sealing layer 4 hardly influences the luminous efficiency and the luminescent color of the light-emitting device.

As can be understood from Table 1, the lifetime of the light-emitting device according to Example 1 is longer than the lifetime of the light-emitting device according to each of the comparative examples. The reason for this is considered to be that, in the light-emitting device according to Example 1, as compared with the light-emitting device according to each of the comparative examples, the sealing layer 4 further reduces the permeation of foreign matters such as moisture from the outside of the light-emitting device to the light-emitting element 3, and thus, reduces the deterioration of the light-emitting element 3.

### Evaluation of Characteristics of Light-Emitting Device: Example 2

A light-emitting device according to another example in which a light-emitting element is sealed with a sealing layer having the same configuration as the sealing layer 4 according to the above-described embodiment was manufactured, and characteristics of the light-emitting device were compared with those of light-emitting devices according to comparative examples. A light-emitting device was manufactured by the procedure described below as a light-emitting device according to Example 2.

First, the substrate 2 and the light-emitting element 3 were manufactured by a method which, except for the following changes, was the same as the method of manufacturing the substrate 2 and the light-emitting element 3 according to Example 1. In the present example, an organic fluorescent material emitting green light was employed as the light-emitting material of the light-emitting layer. Note that, in Example 2, a capping layer formed of an organic material was formed on the green OLED element.

Next, a SiN film having a film thickness of 0.1 μm was film-formed on the substrate 2 and the light-emitting element 3 by a sputtering method, to form the first inorganic film 40. Next, an acrylic resin material having photocurability was film-formed on the first inorganic film 40, and then, the acrylic resin material was irradiated with light to form the hydrophobic organic film 41 having a film thickness of 0.6 μm.

Next, the hygroscopic film 42 was formed by the method described below. First, a resin material including the monomer represented by the following chemical formula and having an amide bond was formed into a film, and cured by ultraviolet irradiation.

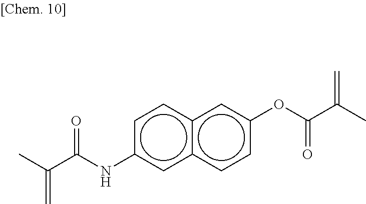

Thus, the hygroscopic film 42 having a film thickness of 0.4 μm was formed. Furthermore, a SiN film having a film thickness of 0.1 μm was film-formed by a sputtering method to form the second inorganic film 43, and thus, the sealing layer 4 was formed. Accordingly, the light-emitting device according to Example 2 was obtained. In the light-emitting device according to Example 2, the moisture permeability of the hydrophobic organic film 41 is 65 g/(m²·24 h), and the moisture permeability of the hygroscopic film 42 is 30 g/(m²· 24 h).

### Evaluation of Characteristics of Light-Emitting Devices: Comparative Examples 5 to 7

In order to evaluate the characteristics of the light-emitting device according to Example 2, light-emitting devices according to Comparative Examples 5 to 7 were also manufactured. The light-emitting device according to each of the comparative examples were manufactured by changing, as described below, the configuration of the sealing layer 4 in the light-emitting device according to Example 2 described above. Note that, in the sealing layer according to each of the comparative examples, the film thickness and the material of the first inorganic film 40 and the second inorganic film 43 are the same as the film thickness and the material of the first inorganic film 40 and the second inorganic film 43 according to Example 2. Furthermore, in the sealing layer according to each of the comparative examples, the materials of the hydrophobic organic film 41 and the hygroscopic film 42 are the same as the materials of the hydrophobic organic film 41 and the hygroscopic film 42 according to Example 2.

The sealing layer of the light-emitting device according to Comparative Example 5 includes the first inorganic film 40, the hydrophobic organic film 41 having a film thickness of 1 μm, and the second inorganic film 43, from the side of the light-emitting element 3. The sealing layer of the light-emitting device according to Comparative Example 6 includes the first inorganic film 40, the hygroscopic film 42 having a film thickness of 20 nm, the hydrophobic organic film 41 having a film thickness of 1 μm, and the second inorganic film 43, from the side of the light-emitting element 3. The sealing layer of the light-emitting device according to Comparative Example 7 includes the first inorganic film 40, the hygroscopic film 42 having a film thickness of 1 μm, and the second inorganic film 43, from the side of the light-emitting element 3.

### Evaluation of Characteristics of Light-Emitting Devices: Results of Evaluation

The characteristics of the light-emitting devices according to Example 2 and each of the comparative examples were measured and summarized in the following Table 2.

TABLE 2

| | External quantum | Chromaticity | Lifetime |
|---|---|---|---|
| | efficiency (%) | (x, y) | (h) |
| Example 2 | 33.6 | (0.280, 0.690) | 135 |
| Comparative Example 5 | 33.5 | (0.280, 0.692) | 75 |
| Comparative Example 6 | 33.6 | (0.278, 0.691) | 90 |
| Comparative Example 7 | 33.6 | (0.278, 0.691) | 110 |

As can be understood from Table 2, the external quantum efficiency of the light-emitting element 3 and the chromaticity of light from the light-emitting element 3 were hardly different between Example 2 and each of the comparative examples. In other words, the above indicates that, in Example 2, the sealing layer 4 hardly influences the luminous efficiency and the luminescent color of the light-emitting device.

As can be understood from Table 2, the lifetime of the light-emitting device according to Example 2 is longer than the lifetime of the light-emitting device according to each of the comparative examples. The reason for this is considered to be that, in the light-emitting device according to Example 2, as compared with the light-emitting device according to each of the comparative examples, the sealing layer 4 further reduces the permeation of foreign matters such as moisture from the outside of the light-emitting device to the light-emitting element 3.

### Second Embodiment

Another embodiment of the disclosure will be described below. Below, in the present specification, for convenience of description, members having the same function as the members described in the above-described embodiments will be denoted by the same reference numerals and signs, and descriptions thereof will not be repeated.

### Light-Emitting Device Including Tandem-Type Light-Emitting Element

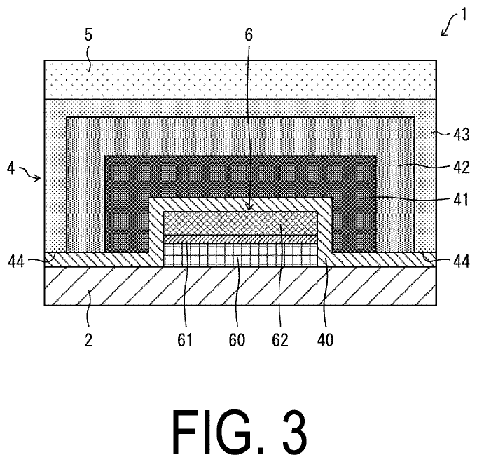

FIG. 3 is a schematic cross-sectional view of the light-emitting device 1 according to the present embodiment. The configuration of the light-emitting device 1 according to the present embodiment is different from the configuration of the light-emitting device 1 according to the previous embodiment only in that, instead of the light-emitting element 3, the light-emitting device 1 includes a tandem-type light-emitting element 6 as the light-emitting element. Therefore, the first inorganic film 40 of the sealing layer 4 covers the tandem-type light-emitting element 6.

The tandem-type light-emitting element 6 includes, on the substrate 2, a first portion 60, a charge generating layer 61, and a second portion 62 in this order. In particular, the tandem-type light-emitting element 6 includes, in each of the first portion 60 and the second portion 62, a light-emitting layer corresponding to the light-emitting layer of the light-emitting element 3 described above. In other words, the tandem-type light-emitting element 6 includes a plurality of light-emitting layers.

For example, the first portion 60 includes, on the substrate 2, an anode, a hole injection layer, a hole transport layer, an electron blocking layer, a light-emitting layer, a hole blocking layer, and an electron transport layer in this order. The tandem-type light-emitting element 6 includes the charge generating layer 61 on the electron transport layer of the first portion 60. The second portion 62 includes, on the charge generating layer 61, a hole transport layer, an electron blocking layer, a light-emitting layer, a hole blocking layer, an electron transport layer, an electron injection layer, and a cathode in this order. The layers of the first portion 60 and the second portion 62 have the same configuration as the layers of the above-described light-emitting element 3.

For example, the charge generating layer 61 is a layer for injecting electrons to the first portion 60 and injecting holes to the second portion 62 when the tandem-type light-emitting element 6 is driven. The charge generating layer 61 includes, for example, an n-type charge generating layer on the side of the first portion 60 and a p-type charge generating layer on the side of the second portion 62. For example, the n-type charge generating layer may contain a combined material of Yb and an organic material having electron transport properties, or a combined material of Li and an organic or inorganic material having electron transport properties. The p-type charge generating layer may contain, for example, an organic material having electron accepting properties. In this case, when a potential difference is generated between the anode of the first portion 60 and the cathode of the second portion 62, electrons are injected from the n-type charge generating layer of the charge generating layer 61 to the first portion 60, and holes are injected from the p-type charge generating layer of the charge generating layer 61 to the second portion 62. For example, the charge generating layer 61 may be a layer that is driven by a circuit substrate formed on the substrate 2, to generate a charge. Alternatively, the charge generating layer 61 may be a layer that generates the above-described charge by a potential difference between the anode of the first portion 60 and the cathode of the second portion 62.

Therefore, holes from the anode of the first portion 60 and electrons from the charge generating layer 61 are injected into the light-emitting layer included in the first portion 60. Furthermore, electrons from the cathode of the second portion 62 and holes from the charge generating layer 61 are injected into the light-emitting layer included in the second portion 62. Thus, in the light-emitting device 1 according to the present embodiment, it is possible to obtain light emission from the light-emitting layers of the first portion 60 and the second portion 62 by driving the tandem-type light-emitting element 6.

Similarly to the light-emitting device 1 according to the previous embodiment, the light-emitting device 1 according to the present embodiment also includes the sealing layer 4 that seals the tandem-type light-emitting element 6. Therefore, the sealing layer 4 according to the present embodiment can more effectively reduce the permeation of moisture from the outside of the light-emitting device 1 into the tandem-type light-emitting element 6.

### Evaluation of Characteristics of Light-Emitting Device: Example 3

A light-emitting device according to another example in which a tandem-type light-emitting element is sealed with a sealing layer having the same configuration as the sealing layer 4 according to the above-described embodiment was manufactured, and characteristics of the light-emitting device were compared with those of light-emitting devices according to comparative examples. A light-emitting device was manufactured by the procedure described below as a light-emitting device according to Example 3.

First, the substrate 2 and the tandem-type light-emitting element 6 were manufactured by a method which, except for the following changes, was the same as the method of manufacturing the substrate 2 and the light-emitting element 3 according to Example 1.

In the present example, after preparing the substrate 2, a hole injection layer, a hole transport layer, an electron blocking layer, a light-emitting layer, a hole blocking layer, an electron transport layer, and an electron injection layer were formed by vapor deposition on the anode formed on the substrate 2, to form the first portion 60. Next, the charge generating layer 61 having a predetermined film thickness was formed on the electron injection layer of the first portion 60 under predetermined vapor deposition conditions. Subsequently, a hole injection layer, a hole transport layer, an electron blocking layer, a light-emitting layer, a hole blocking layer, an electron transport layer, an electron injection layer, and a cathode were formed on the charge generating layer 61 by vapor deposition to form the second portion 62. The materials, the vapor deposition conditions, and the film thickness of the layers of the first portion 60 and the second portion 62 were the same as those of the corresponding layers of the light-emitting element 3 according to Example 1. Note that, in Example 3, a capping layer formed of an organic material was formed on the tandem-type light-emitting element 6.

Next, a SiN film having a film thickness of 0.1 μm was film-formed on the substrate 2 and the tandem-type light-emitting element 6 by a sputtering method, to form the first inorganic film 40. Subsequently, an acrylic resin material having photocurability was film-formed on the first inorganic film 40, and then, the acrylic resin material was irradiated with light to form the hydrophobic organic film 41 having a film thickness of 0.3 μm. Next, the same method as the method described in Example 1 was used to form the hygroscopic film 42 containing the same material as that of Example 1 and having a film thickness of 0.6 μm. Furthermore, a SiN film having a film thickness of 0.1 μm was film-formed by a sputtering method to form the second inorganic film 43, and thus, the sealing layer 4 was formed. Accordingly, the light-emitting device according to Example 3 was obtained. Note that, in the light-emitting device according to Example 3, the moisture permeability of the hydrophobic organic film 41 is 60 g/(m²·24 h), and the moisture permeability of the hygroscopic film 42 is 25 g/(m²·24 h).

### Evaluation of Characteristics of Light-Emitting Devices: Comparative Examples 8 to 11

In order to evaluate the characteristics of the light-emitting device according to Example 3, light-emitting devices according to Comparative Examples 8 to 11 were also manufactured. The light-emitting devices according to Comparative Examples 8 to 11 were manufactured by changing the configuration of the sealing layer 4 in the light-emitting device according to Example 3 described above, to the configuration of the sealing layer according to each of Comparative Examples 1 to 4.

### Evaluation of Characteristics of Light-Emitting Devices: Results of Evaluation

The characteristics of the light-emitting devices according to Example 3 and each of the comparative examples were measured and summarized in the following Table 3.

TABLE 3

| | External quantum | Chromaticity | Lifetime |
|---|---|---|---|
| | efficiency (%) | (x, y) | (h) |
| Example 3 | 23.6 | (0.141, 0.038) | 285 |
| Comparative Example 8 | 23.3 | (0.14, 0.036) | 133 |
| Comparative Example 9 | 23.5 | (0.139, 0.038) | 142 |
| Comparative Example 10 | 23.8 | (0.139, 0.038) | 183 |
| Comparative Example 11 | 23.3 | (0.141, 0.038) | 201 |

As can be understood from Table 3, the external quantum efficiency of the tandem-type light-emitting element 6 and the chromaticity of light from the tandem-type light-emitting element 6 were hardly different between Example 3 and each of the comparative examples. In other words, the above indicates that, in Example 3, the sealing layer 4 hardly influences the luminous efficiency and the luminescent color of the tandem-type light-emitting element.

As can be understood from Table 3, the lifetime of the light-emitting device according to Example 3 is longer than the lifetime of the light-emitting device according to each of the comparative examples. The reason for this is considered to be that, in the light-emitting device according to Example 3, as compared with the light-emitting device according to each of the comparative examples, the sealing layer 4 further reduces the permeation of foreign matters such as moisture from the outside of the light-emitting device to the tandem-type light-emitting element 6.

### Third Embodiment

### Buffer Layer

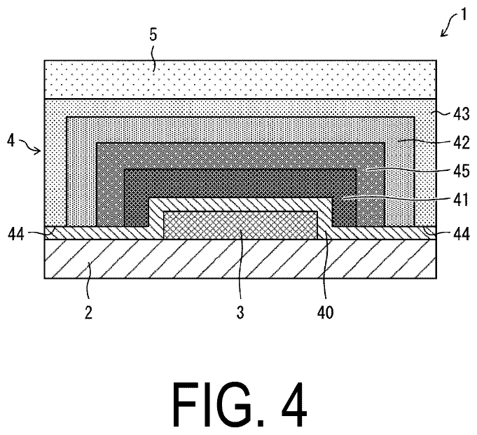

FIG. 4 is a schematic cross-sectional view of the light-emitting device 1 according to the present embodiment. The configuration of the light-emitting device 1 according to the present embodiment is different from the configuration of the light-emitting device 1 according to the first embodiment only in that the sealing layer 4 includes a buffer layer 45 between the hydrophobic organic film 41 and the hygroscopic film 42.

For example, similarly to the hygroscopic film 42, the buffer layer 45 is an organic sealing film having hygroscopicity, and in particular, has a function of absorbing foreign matters such as moisture that permeates from the outside of the light-emitting device 1 on the side of the sealing layer 4 into the light-emitting element 3, and delaying the permeation of the foreign matters into the light-emitting element 3. In particular, the buffer layer 45 may be formed at a position covering the hydrophobic organic film 41, and the hygroscopic film 42 may be formed at a position covering the buffer layer 45.

In the present embodiment, the hydrophobicity of the buffer layer 45 may be higher than that of the hygroscopic film 42 and lower than that of the hydrophobic organic film 41. For example, the buffer layer 45 may contain an organic polymer that is more hydrophobic than the hygroscopic film 42.

For example, similarly to the hygroscopic film 42, the buffer layer 45 may include at least one of a first organic polymer and a second organic polymer. In this case, the buffer layer 45 may include, for example, a first organic polymer having a lower concentration of the hydrophilic functional group with respect to the molecular backbone having hydrophobicity, than the first organic polymer included in the hygroscopic film 42. Furthermore, the buffer layer 45 may include, for example, a second organic polymer having a lower ratio of the hydrophilic functional group with respect to the hydrophobic functional group, than the second organic polymer included in the hygroscopic film 42.

For example, similarly to the hygroscopic film 42, the buffer layer 45 may be formed by applying a material containing an organic polymer to form a film. In particular, the buffer layer 45 and the hygroscopic film 42 may be individually applied and film-formed, or may be applied and film-formed in the same step.

For example, in a step of forming the buffer layer 45 and the hygroscopic film 42, a coating material containing organic polymers having different hydrophobicity may be applied onto the hydrophobic organic film 41. In this case, the organic polymer having higher hydrophobicity in the coating material may move to the hydrophobic organic film 41 due to the weight of the organic polymer or attraction by the hydrophobic organic film 41 having hydrophobicity. In this state, the buffer layer 45 and the hygroscopic film 42 may be simultaneously formed by curing the coating material.

As described above, in the present embodiment, the buffer layer 45 is more hydrophobic than the hygroscopic film 42. Therefore, as described above, the moisture absorbed by the hygroscopic film 42 via the pin holes H of the second inorganic film 43 is more likely to be released to the pin holes H of the second inorganic film 43 and not likely to permeate into the buffer layer 45 which is hydrophobic and solid.

In the present embodiment, as described above, the buffer layer 45 is less hydrophobic than the hydrophobic organic film 41. Therefore, even when moisture permeates into the buffer layer 45 via the hygroscopic film 42, the moisture is more likely to permeate into the hygroscopic film 42 having high hydrophilicity and not likely to permeate into the hydrophobic organic film 41 having high hydrophobicity.

Therefore, among the moisture absorbed by the hygroscopic film 42 or the buffer layer 45, the amount of moisture released to the outside of the light-emitting device 1 is greater than the amount of moisture permeating into the light-emitting element 3. Thus, the sealing layer 4 efficiently releases the moisture absorbed by the hygroscopic film 42 or the buffer layer 45 to the outside of the light-emitting device 1, and reduces the permeation of moisture into the light-emitting element 3.

Furthermore, the hydrophobicity of the buffer layer 45 may be higher than that of the hygroscopic film 42 and lower than that of the hydrophobic organic film 41. Therefore, the adhesion between the hydrophobic organic film 41 and the buffer layer 45 and the adhesion between the buffer layer 45 and the hygroscopic film 42 are both higher than the adhesion between the hydrophobic organic film 41 and the hygroscopic film 42. Therefore, in the light-emitting device 1 according to the present embodiment, it is possible to further reduce the permeation of foreign matters such as moisture from in-between the layers of the sealing layer 4.

### Fourth Embodiment

### Inorganic Intermediate Film

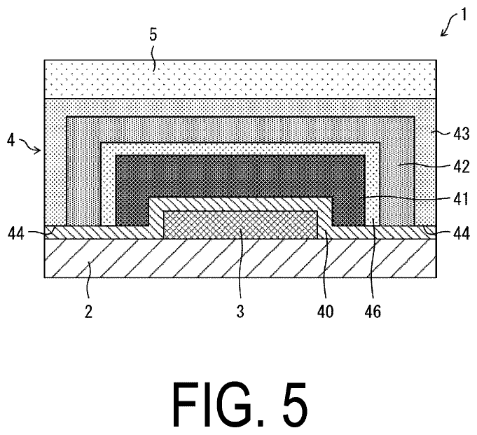

FIG. 5 is a schematic cross-sectional view of the light-emitting device 1 according to the present embodiment. The configuration of the light-emitting device 1 according to the present embodiment is different from the configuration of the light-emitting device 1 according to the first embodiment only in that the sealing layer 4 includes an inorganic intermediate film 46 between the hydrophobic organic film 41 and the hygroscopic film 42.

The inorganic intermediate film 46 may have the same configuration as the first inorganic film 40 or the second inorganic film 43, except for a formation position of the films. In particular, the inorganic intermediate film 46 may be formed at a position covering the hydrophobic organic film 41, and the hygroscopic film 42 may be formed at a position covering the inorganic intermediate film 46.

The inorganic intermediate film 46 reduces the permeation of moisture from the hygroscopic film 42 into the hydrophobic organic film 41. Thus, the sealing layer 4 releases more efficiently the moisture absorbed by the hygroscopic film 42 to the outside of the light-emitting device 1, and reduces the permeation of moisture into the light-emitting element 3.

Furthermore, even in a case in which the above-described pin holes H are formed in the inorganic intermediate film 46, after the inorganic intermediate film 46 is formed, the hygroscopic film 42 is formed by film formation in the pin holes H. Thus, the hygroscopic film 42 contacts the hydrophobic organic film 41 in the pin holes H of the inorganic intermediate film 46. Therefore, the moisture from the hygroscopic film 42 is more likely to be released to the outside of the light-emitting device 1 via the pin holes H of the second inorganic film 43, and is less likely to permeate into the hydrophobic organic film 41 via the pin holes H of the inorganic intermediate film 46. Thus, the sealing layer 4 releases more efficiently the moisture absorbed by the hygroscopic film 42 to the outside of the light-emitting device 1, and reduces the permeation of moisture into the light-emitting element 3.

### Fifth Embodiment

### Color Light-Emitting Device

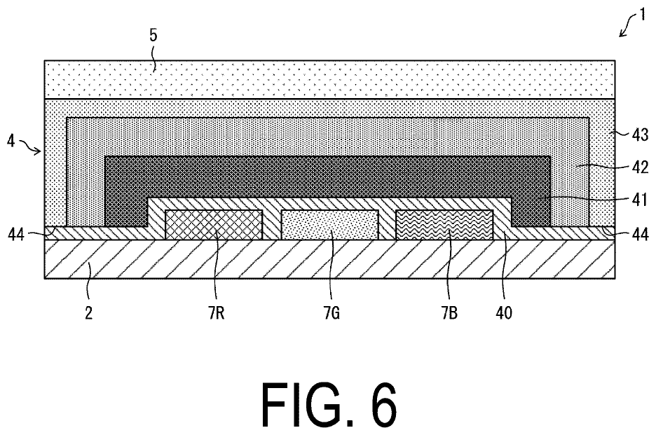

FIG. 6 is a schematic cross-sectional view of the light-emitting device 1 according to the present embodiment. The configuration of the light-emitting device 1 according to the present embodiment is different from the configuration of the light-emitting device 1 according to the first embodiment only in that, instead of the light-emitting element 3, the light-emitting device 1 includes a plurality of light-emitting elements including a red light-emitting element 7R, a green light-emitting element 7G, and a blue light-emitting element 7B.

The red light-emitting element 7R, the green light-emitting element 7G, and the blue light-emitting element 7B respectively include light-emitting layers that emit red light, green light, and blue light. The red light-emitting element 7R, the green light-emitting element 7G, and the blue light-emitting element 7B have the same configuration as the light-emitting element 3 described above, except for the colors of the light emitted by the light-emitting layers.

The anodes of the red light-emitting element 7R, the green light-emitting element 7G, and the blue light-emitting element 7B may each be electrically connected to a circuit substrate formed on the substrate 2, or may be individually driven. Therefore, the light-emitting device 1 according to the present embodiment may individually emit at least one of red light, green light, and blue light. Therefore, the light-emitting device 1 according to the present embodiment may serve as a color light-emitting device.

The light-emitting device 1 may include a plurality of sets of light-emitting elements each including the red light-emitting element 7R, the green light-emitting element 7G, and the blue light-emitting element 7B and being arranged on the substrate 2 in a two dimensional manner. In this case, each of the sets of light-emitting elements including the red light-emitting element 7R, the green light-emitting element 7G, and the blue light-emitting element 7B may be individually driven, so that the light-emitting device 1 functions as a color display device.

In the present embodiment, the first inorganic film 40 is formed at a position covering each of the red light-emitting element 7R, the green light-emitting element 7G, and the blue light-emitting element 7B. Therefore, the sealing layer 4 seals the red light-emitting element 7R, the green light-emitting element 7G, and the blue light-emitting element 7B. Accordingly, the sealing layer 4 according to the present embodiment can more effectively reduce the permeation of moisture from the outside of the light-emitting device 1 into each of the red light-emitting element 7R, the green light-emitting element 7G, and the blue light-emitting element 7B.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting device, comprising:
a light-emitting element;
a first inorganic film covering the light-emitting element;
a hydrophobic organic film located outside the first inorganic film; and
a hygroscopic film located outside the hydrophobic organic film.

2. The light-emitting device according to claim 1, further comprising
a second inorganic film covering the hygroscopic film.

3. The light-emitting device according to claim 2,
wherein the second inorganic film is in direct contact of a peripheral portion of the first inorganic film.

4-5. (canceled)

6. The light-emitting device according to claim 1,
wherein a moisture permeability of the hygroscopic film is ½ or less of a moisture permeability of the hydrophobic organic film.

7. The light-emitting device according to claim 1,
wherein the moisture permeability of the hygroscopic film is ⅓ or less of the moisture permeability of the hydrophobic organic film.

8. The light-emitting device according to claim 1,
wherein the moisture permeability of the hygroscopic film is 30 g/(m²·24 h) or less.

9. The light-emitting device according to claim 1,
wherein the moisture permeability of the hydrophobic organic film is 60 g/(m²·24 h) or greater and 1000 g/(m²·24 h) or less.

10-13. (canceled)

14. The light-emitting device according to claim 1,
wherein the hygroscopic film includes
a first organic polymer including a hydrophilic functional group and having a molecular backbone of which at least a part is hydrophobic, and/or
a second organic polymer including a hydrophilic functional group and a hydrophobic functional group.

15-17. (canceled)

18. The light-emitting device according to claim 14,
wherein the first organic polymer includes at least one selected from the group consisting of polymers represented by General Formula (1) 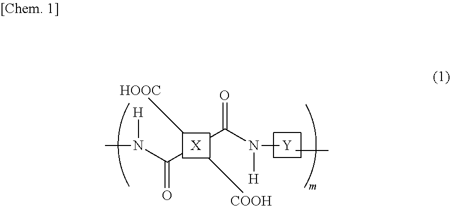
where in General Formula (1), X represents any one of the following components, and 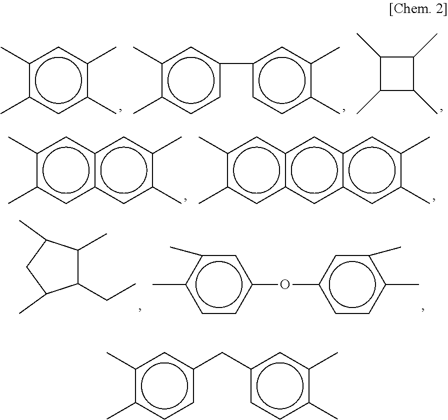
Y represents any one of the following components

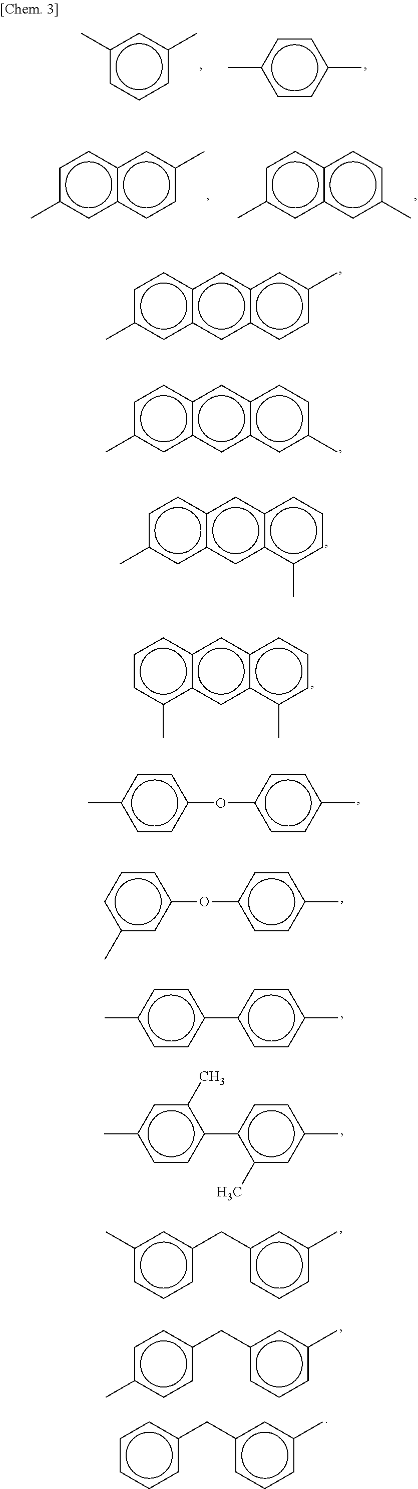

19. The light-emitting device according to claim 14,
wherein the first organic polymer includes at least one selected from the group consisting of polymers represented by the following chemical formulae

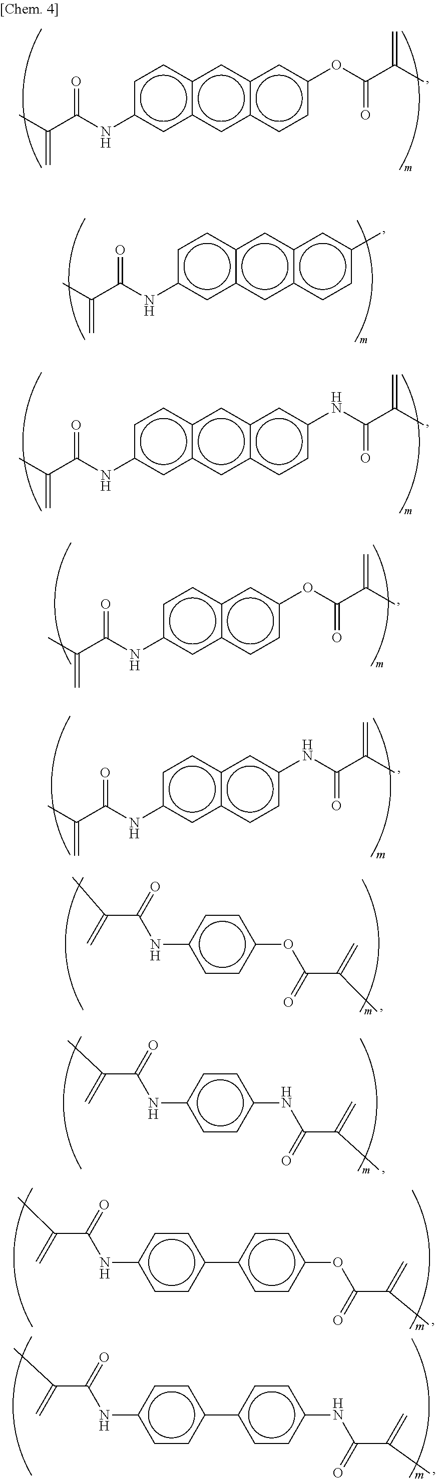

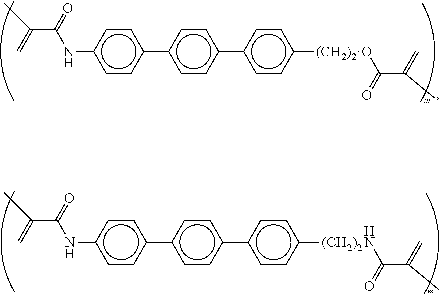

20-23. (canceled)

24. The light-emitting device according to claim 14,
wherein the second organic polymer includes at least one selected from the group consisting of polymers represented by General Formula (2) 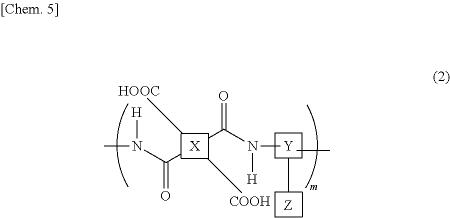
where in General Formula (2), X represents any one of the following components 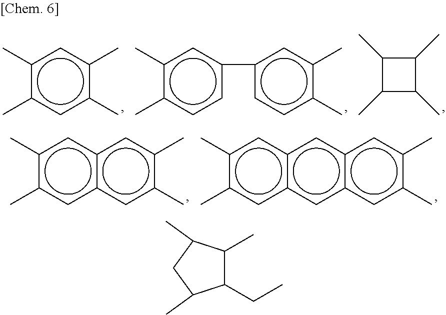
Y represents any one of the following components, and 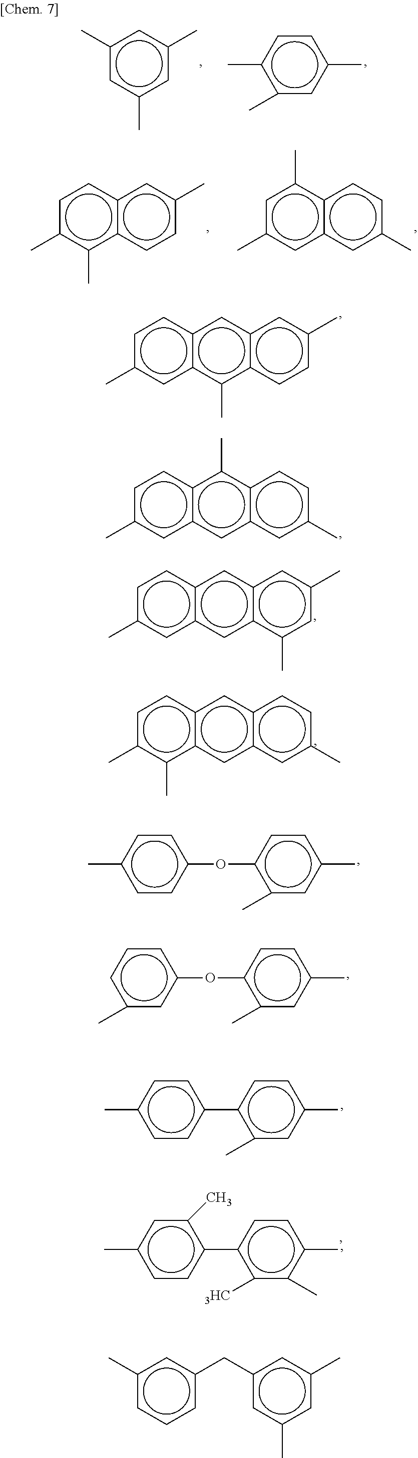 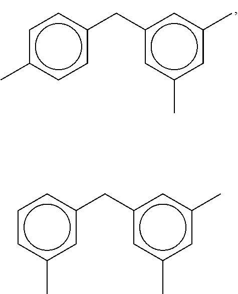
Z represents any one of the following components

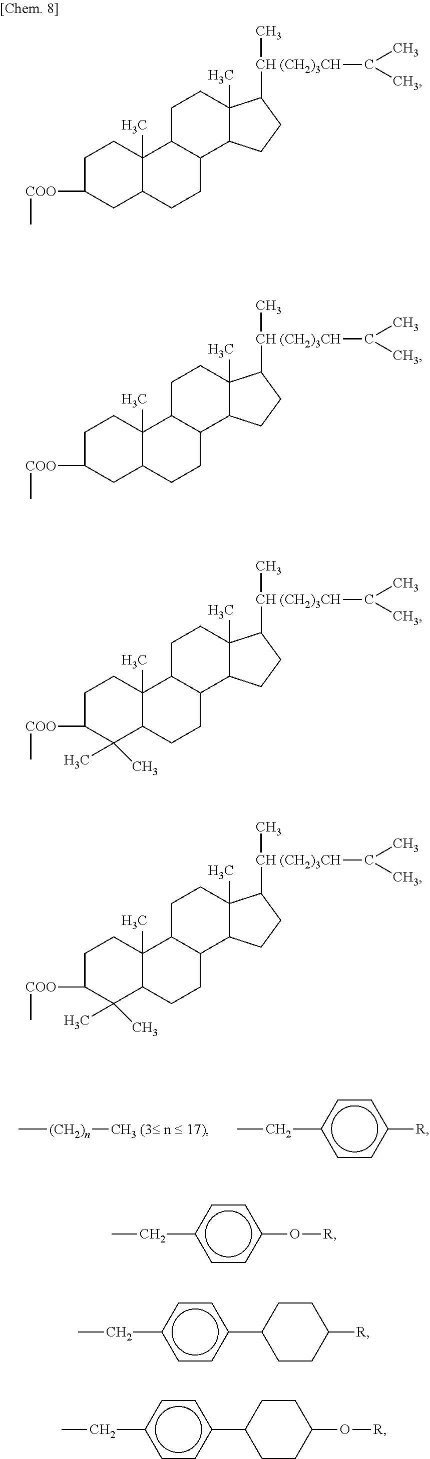

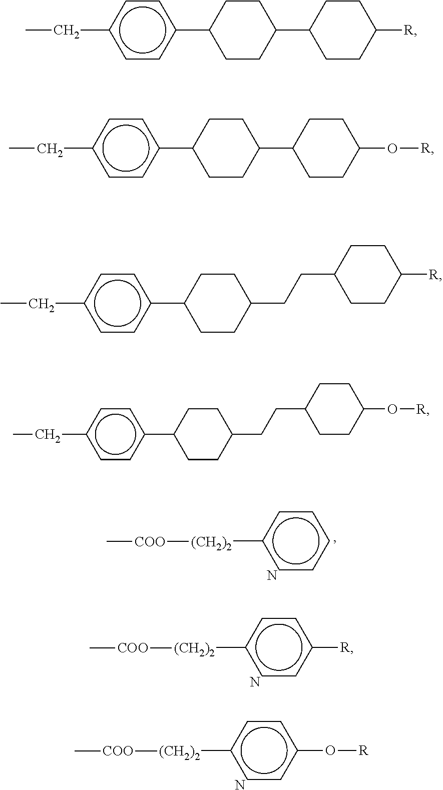

25. The light-emitting device according to claim 14,
wherein the second organic polymer includes at least one selected from the group consisting of polymers represented by the following chemical formulae, in which X represents an alkyl group

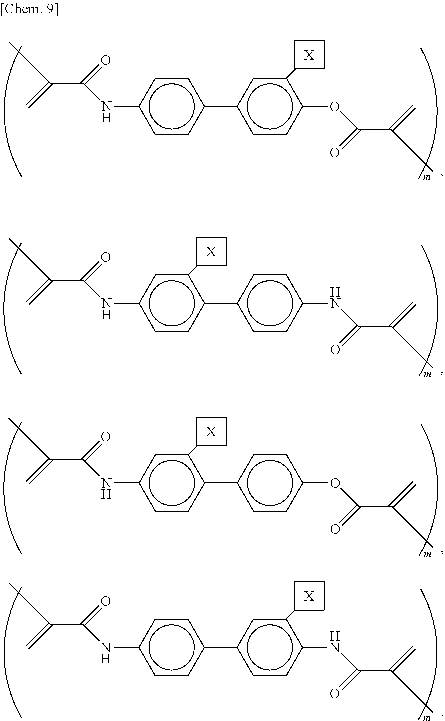

26. The light-emitting device according to claim 14,
wherein the hygroscopic film includes the first organic polymer and the second organic polymer.

27. The light-emitting device according to claim 26,
wherein the molecular backbone of the first organic polymer is the same as a molecular backbone of the second organic polymer.

28. The light-emitting device according to claim 26,
wherein a ratio of an amount of substance in the second organic polymer with respect to an amount of substance in the first organic polymer in the hygroscopic film is 0.05 or greater and 20 or less.

29. The light-emitting device according to claim 26,
wherein a concentration of the second organic polymer in a portion of the hygroscopic film on a side of the hydrophobic organic film is higher than a concentration of the second organic polymer in a portion of the hygroscopic film on a side opposite to the side of the hydrophobic organic film.

30-31. (canceled)

32. The light-emitting device according to claim 1,
wherein the light-emitting element includes
a red light-emitting element configured to emit red light,
a green light-emitting element configured to emit green light, and
a blue light-emitting element configured to emit blue light.

33. The light-emitting device according to claim 1,
wherein the light-emitting element includes a tandem-type light-emitting element including a plurality of light-emitting layers.

34. (canceled)

35. The light-emitting device according to claim 1,
wherein the light-emitting element includes a quantum dot light-emitting element including a quantum dot as a light-emitting material.
